(19) United States
(12) Patent Application Publication
(10) Pub. No.: US 2023/0299032 A1
(43) Pub. Date: Sep. 21, 2023

(54) MICROELECTRONIC ASSEMBLIES INCLUDING NANOWIRE AND SOLDER INTERCONNECTS

(71) Applicant: Intel Corporation, Santa Clara, CA (US)

(72) Inventors: Bernd Waidhas, Pettendorf (DE); Jan Proschwitz, Riesa SN (DE); Stefan Reif, Munich (DE); Vishnu Prasad, Munich (DE)

(73) Assignee: Intel Corporation, Santa Clara, CA (US)

(21) Appl. No.: 17/699,209

(22) Filed: Mar. 21, 2022

(51) Int. Cl. H01L 23/00

(52) U.S. Cl. CPC H01L 24/16; H01L 24/13; H01L 24/32; H01L 24/73; H01L 24/81; H01L 2224/13016; H01L 2224/13076; H01L 2224/13105; H01L 2224/13109; H01L 2224/13111; H01L 2224/13113; H01L 2224/1312; H01L 2224/13139; H01L 2224/13144; H01L 2224/13147; H01L 2224/13155; H01L 2224/13164; H01L 2224/16227; H01L 2224/32225; H01L 2224/73204; H01L 2224/81439; H01L 2224/81444; H01L 2224/81447; H01L 2224/81455; H01L 2224/81464; H01L 2924/013; H01L 2924/014

(57) ABSTRACT

Disclosed herein are microelectronic assemblies, as well as related apparatuses and methods. In some embodiments, a microelectronic assembly may include a die having a first conductive contact on a surface; a substrate having a second conductive contact on a surface; and an interconnect electrically coupling the first conductive contact of the die and the second conductive contact of the substrate, wherein the interconnect includes a portion of a nanowire on the second conductive contact and an intermetallic compound (IMC) surrounding at least a portion of the nanowire on the second conductive contact.

### BACKGROUND

In conventional microelectronic packages, a die may be attached to a package substrate by solder. Such a package may be limited in the achievable interconnect density between the package substrate and the die, the achievable speed of signal transfer, and the achievable miniaturization, for example.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a side, cross-sectional view of an exemplary microelectronic assembly, in accordance with various embodiments.

FIG. 2 is a side, cross-sectional view of another exemplary microelectronic assembly, in accordance with various embodiments.

FIG. 3 is a side, cross-sectional view of another exemplary microelectronic assembly, in accordance with various embodiments.

FIGS. 4A-4C are side, cross-sectional views of an exemplary process for manufacturing a microelectronic assembly, in accordance with various embodiments.

FIGS. 5A-5D are side, cross-sectional views of another exemplary process for manufacturing a microelectronic assembly, in accordance with various embodiments.

FIG. 6 is a flow diagram of an example method of manufacturing a microelectronic assembly, in accordance with various embodiments.

FIGS. 7A and 7B are top views of a wafer and dies that may be used with any of the embodiments of the microelectronic assemblies disclosed herein.

FIG. 7C is a cross-sectional side view of an integrated circuit device that may be used with any of the embodiments of the microelectronic assemblies disclosed herein.

FIG. 8 is a cross-sectional side view of an integrated circuit device assembly that may include any of the embodiments of the microelectronic assemblies disclosed herein.

FIG. 9 is a block diagram of an example computing device that may include any of the embodiments of the microelectronic assemblies disclosed herein.

### DETAILED DESCRIPTION

Disclosed herein are microelectronic assemblies, as well as related apparatuses and methods. For example, in some embodiments, a microelectronic assembly may include a die having a first conductive contact on a surface; a substrate having a second conductive contact on a surface; and an interconnect electrically coupling the first conductive contact of the die and the second conductive contact of the substrate, wherein the interconnect includes a portion of a nanowire on the second conductive contact and an intermetallic compound (IMC) surrounding at least a portion of the nanowire on the second conductive contact.

To achieve high interconnect density in a microelectronics package, some approaches for fine pitch below 10 microns like hybrid bonding require costly manufacturing operation. The microelectronic structures and assemblies disclosed herein may achieve interconnect densities as high or higher than conventional approaches without the expense of costly manufacturing operations. Further, the microelectronic structures and assemblies disclosed herein offer new flexibility to electronics designers and manufacturers, allowing them to select an architecture that achieves their device goals without excess cost or manufacturing complexity.

In the following detailed description, reference is made to the accompanying drawings that form a part hereof, wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. The accompanying drawings are not necessarily drawn to scale. Although many of the drawings illustrate rectilinear structures with flat walls and right-angle corners, this is simply for ease of illustration, and actual devices made using these techniques will exhibit rounded corners, surface roughness, and other features.

Various operations may be described as multiple discrete actions or operations in turn, in a manner that is most helpful in understanding the disclosed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C). The term “between,” when used with reference to measurement ranges, is inclusive of the ends of the measurement ranges. As used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous, as are a “die,” an “IC die,” “a microelectronic component,” and “an electrical component.” The terms “top” and “bottom” may be used herein to explain various features of the drawings, but these terms are simply for ease of discussion, and do not imply a desired or required orientation. As used herein, the term “insulating” means “electrically insulating,” unless otherwise specified. Throughout the specification, and in the claims, the term “coupled” means a direct or indirect connection, such as a direct electrical, mechanical, or magnetic connection between the things that are connected or an indirect connection, through one or more passive or active intermediary devices. The meaning of “a,” “an,” and “the” include plural references. The meaning of “in” includes “in” and “on.”

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

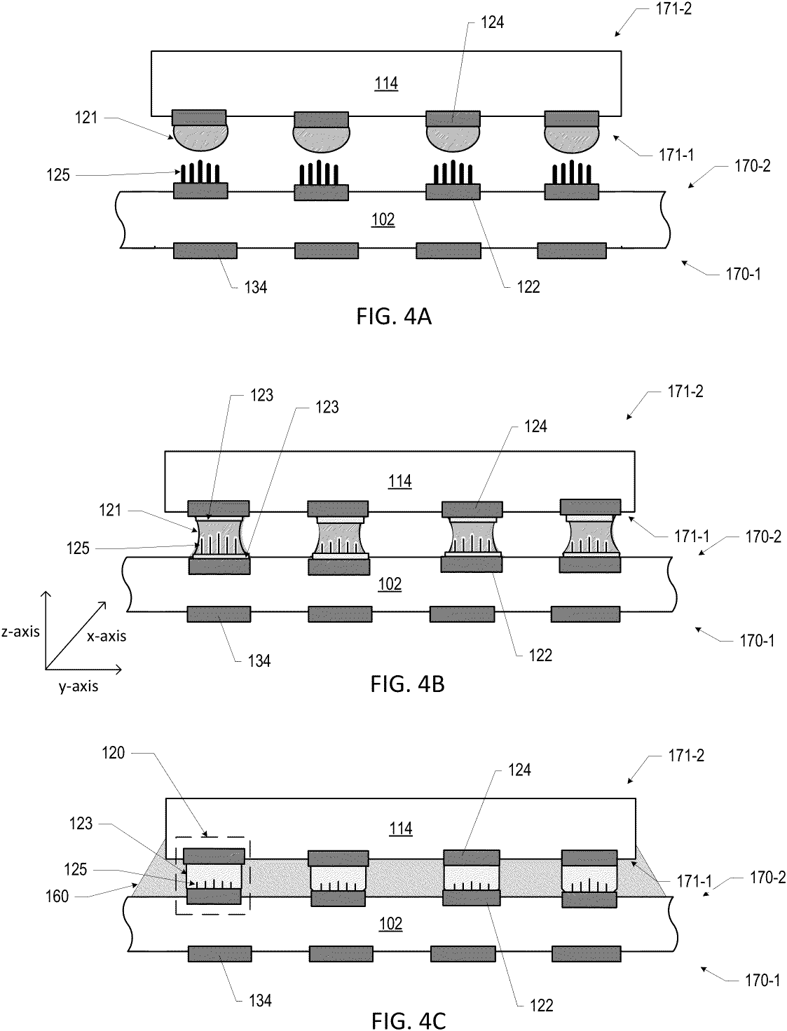

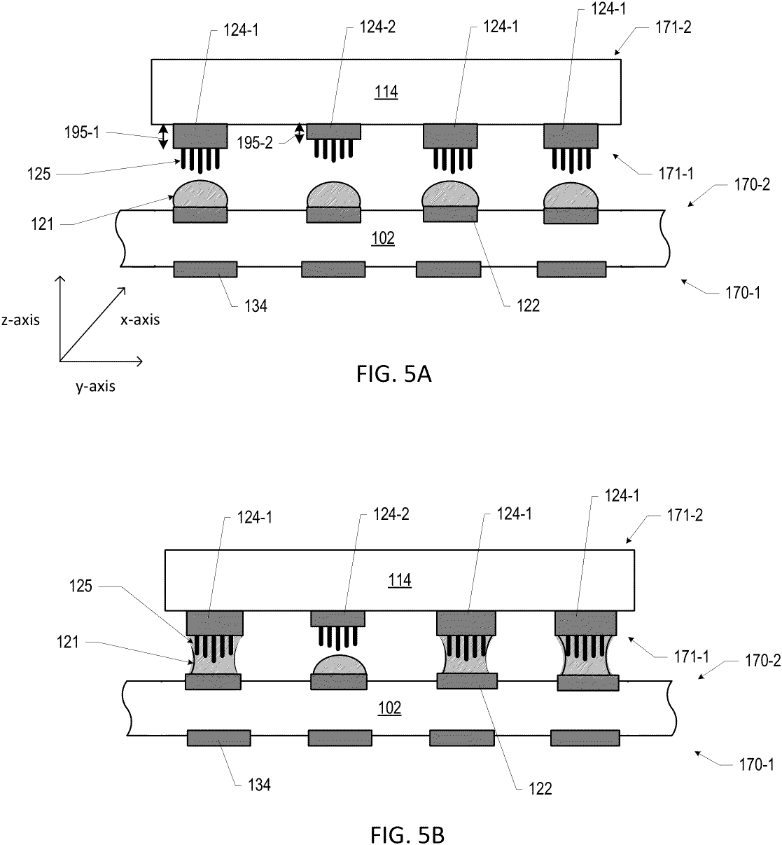

When used to describe a range of dimensions, the phrase “between X and Y” represents a range that includes X and Y. For convenience, the phrase “FIG. 4” may be used to refer to the collection of drawings of FIGS. 4A-4C, the phrase “FIG. 5” may be used to refer to the collection of drawings of FIGS. 5A-5D, etc. Although certain elements may be referred to in the singular herein, such elements may include multiple sub-elements. For example, “an insulating material” may include one or more insulating materials.

An “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “metal traces,” “lines,” “metal lines,” “wires,” “metal wires,” “trenches,” or “metal trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PIC. In such cases, the term “interconnect” may refer to optical waveguides (e.g., structures that guide and confine light waves), including optical fiber, optical splitters, optical combiners, optical couplers, and optical vias.

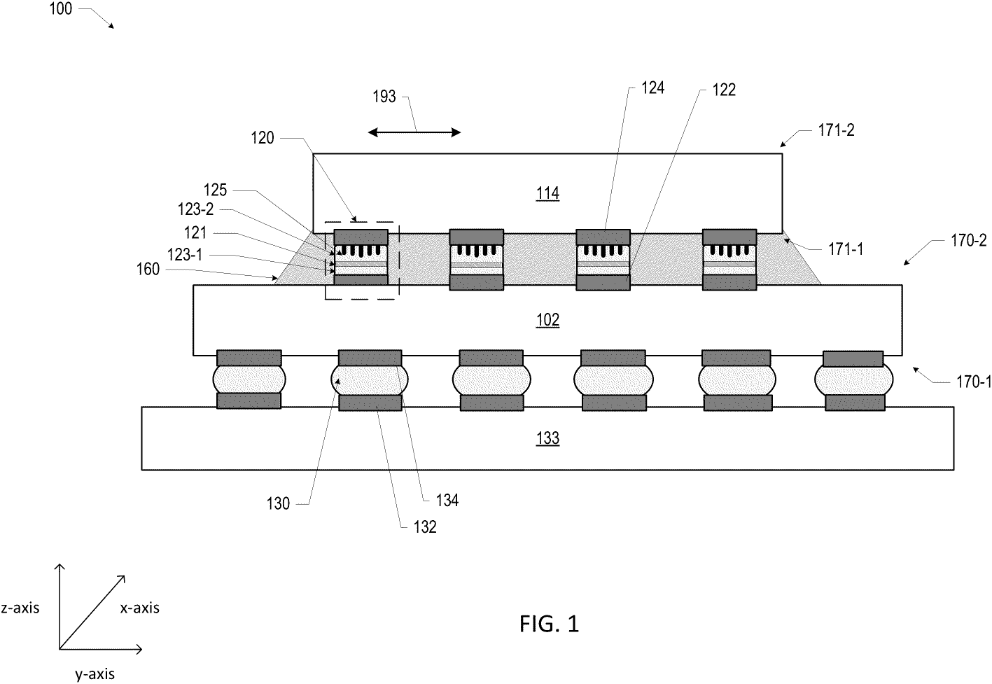

FIG. 1 is a side, cross-sectional view of a microelectronic assembly 100, in accordance with various embodiments. The microelectronic assembly 100 may include a substrate 102 with a die 114 disposed thereon. The die 114 may be electrically coupled to the substrate 102 by interconnects 120, also referred to herein as “first level interconnects.” The substrate 102 may have a bottom surface (e.g., a first surface 170-1) and an opposing top surface (e.g., a second surface 170-2). The substrate 102 may have first conductive contacts 134 on the first surface 170-1 and second conductive contacts 122 on the second surface 170-2. The die 114 may have a bottom surface (e.g., a first surface 171-1) and an opposing top surface (e.g., a second surface 171-2). The die 114 may have the first surface 171-1 having conductive contacts 124. The conductive contacts 124 on the first surface 171-1 of the die 114 may be coupled to the conductive contacts 122 on the second surface 170-2 of the substrate 102 via the first level interconnects 120. As used herein, a “conductive contact” may refer to a portion of conductive material (e.g., one or more metals) serving as part of an interface between different components; although some of the conductive contacts discussed herein are illustrated in a particular manner in various ones of the accompanying drawings, any conductive contacts may be recessed in, flush with, or extending away from a surface of a component, and may take any suitable form (e.g., a conductive pad or socket).

The first level interconnects 120 may include nanowires 125, a solder material 121 (e.g., solder bumps or balls), and an intermetallic compound (IMC) 123 (e.g., IMC 123-1, 123-2) that conductively couple the conductive contacts 124 on the die 114 and second conductive contacts 122 on the substrate 102. The interconnects 120 may include one or more IMCs 123. For example, as shown in FIG. 1, the interconnect 120 includes a first IMC 123-1 at the surface of the conductive contacts 122 and a second IMC 123-2 at the surface of the conductive contacts 124 with the solder material 121 between the first and second IMCs 123-1, 123-2 (e.g., solder material 121 that did not completely convert to an IMC 123). The IMC 123-2 may be formed at a surface of the conductive contact 124 and at a surface of the nanowires 125 then may surround the nanowires 125 and extend to the surface of the conductive contact 124. In some embodiments, when forming the interconnect 120, the nanowires 125 may be deposited on a surface of conductive contacts 124 and the solder material 121 may be deposited on a surface of conductive contacts 122, as described below with reference to FIG. 5. For example, during a solder reflow process, the nanowires 125 on conductive contacts 124 may contact and pull the solder material 121 on conductive contacts 122 on the substrate, by capillary action, towards the conductive contacts 124 on the die, which may reduce bridging (e.g., reduce solder seepage by enabling a self-centering effect through wetting force and solder surface tension) to adjacent interconnects 120 and may enable smaller interconnect pitches. For example, in some embodiments, interconnects 120 may have a pitch 193 between 3 microns and 20 microns. In some embodiments, interconnects 120 may have a pitch 193 between 3 microns and 10 microns. As used herein, pitch is measured center-to-center (e.g., from a center of a conductive contact to a center of an adjacent conductive contact or from a center of an interconnect to a center of an adjacent interconnect). When the IMC 123 forms, the nanowires 125 may be reduced in height (e.g., z-direction) and/or diameter (e.g., y-direction and/or x-direction), as described below with reference to FIG. 4. In some embodiments, when forming the interconnect 120, the nanowires 125 may be deposited on a surface of conductive contacts 122 on the substrate and the solder material 121 may be deposited on a surface of conductive contacts 124 on the die 114, as described below with reference to FIG. 4.

The solder material 121 may include any suitable solder material and may include a solder material that, during reflow, forms an IMC 123, such as an IMC in the form of Cu₃Sn. In some embodiments, the solder material 121 may include a lower-temperature solder or a conventional solder. As used herein, a “lower-temperature” solder includes a solder with a melting point below 241° C. In some embodiments, a lower-temperature solder may include tin and bismuth (e.g., eutectic tin bismuth) or tin, silver, and bismuth. In some embodiments, a lower-temperature solder may include indium, indium and tin, antimony, or gallium. A “conventional solder” includes solder with a melting point equal to 241° C. and may include, for example, tin or tin and silver.

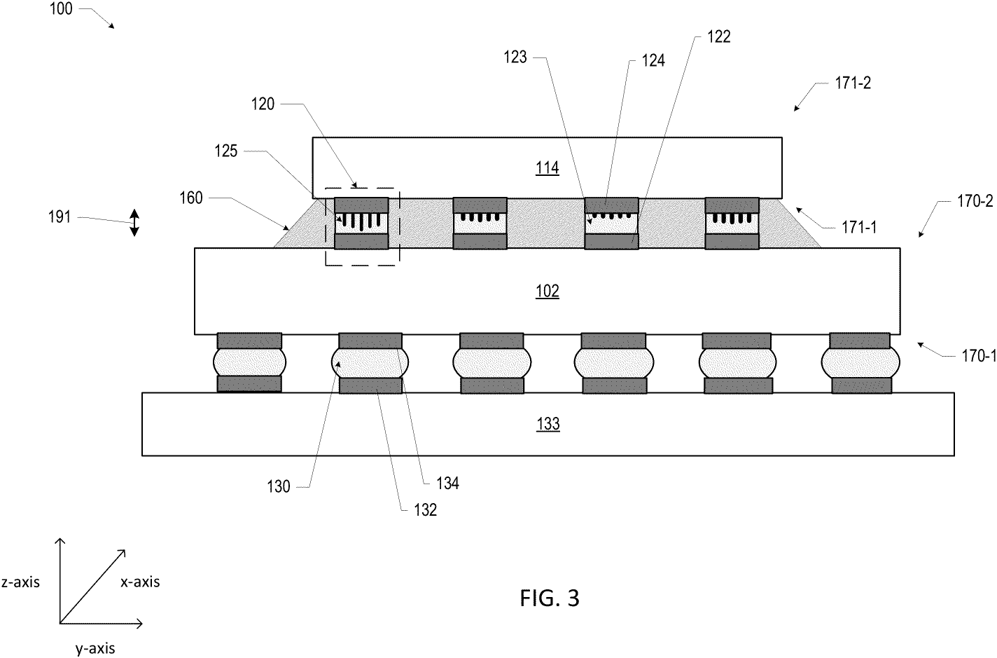

The nanowires 125 may be made of any suitable conductive material, including a metal, such as copper, nickel, gold, silver, or palladium, or other metals or alloys, for example. The nanowires 125 may be formed using any suitable process, for example, electroplating, as described below with reference to FIG. 4. The nanowires 125 may have any suitable shape, including straight or hooked, among others. The nanowires may have any suitable size, as described below with reference to FIG. 3.

In some embodiments, the first level interconnects 120 may be surrounded by an underfill material 160 (e.g., the underfill material 160 may be disposed between the die 114 and the second surface 170-2 of the substrate 102). The underfill material 160 may be any suitable material. The underfill material 160 may be an insulating material, such as an appropriate epoxy material. In some embodiments, the underfill material 160 may include a capillary underfill, non-conductive film (NCF), or molded underfill. The underfill material 160 may be selected to have a CTE that may mitigate or minimize the stress between the die 114 and the substrate 102. In some embodiments, the underfill material 160 may include an epoxy flux that assists with soldering the die 114 to the substrate 102 when forming the first level interconnects 120, and then polymerizes and encapsulates the first level interconnects 120. In some embodiments, the CTE of the underfill material 160 may have a value that is intermediate to the CTE of the substrate 102 (e.g., the CTE of the dielectric material of the substrate 102) and a CTE of the die 114.

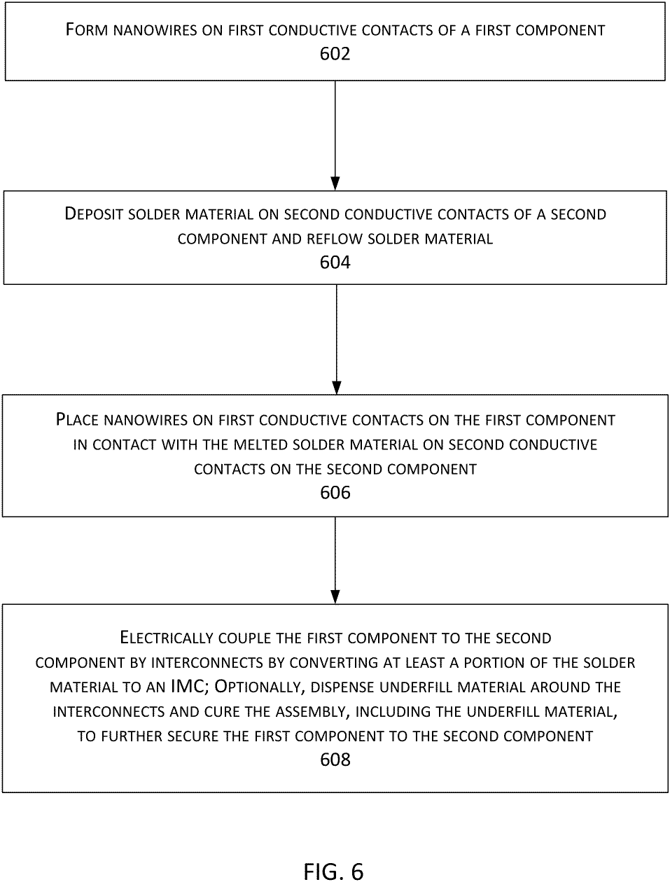

The die 114 disclosed herein may include an insulating material (e.g., a dielectric material formed in multiple layers, as known in the art) and multiple conductive pathways formed through the insulating material. In some embodiments, the insulating material of a die 114 may include a dielectric material, such as silicon dioxide, silicon nitride, oxynitride, polyimide materials, glass reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments, the insulating material of a die 114 may include a semiconductor material, such as silicon, germanium, or a III-V material (e.g., gallium nitride), and one or more additional materials. For example, an insulating material may include silicon oxide or silicon nitride. The conductive pathways in a die 114 may include conductive traces and/or conductive vias, and may connect any of the conductive contacts in the die 114 in any suitable manner (e.g., connecting multiple conductive contacts on a same surface or on different surfaces of the die 114). Example structures that may be included in the dies 114 disclosed herein are discussed below with reference to FIG. 7. The conductive pathways in the dies 114 may be bordered by liner materials, such as adhesion liners and/or barrier liners, as suitable.

The substrate 102 may include an insulating material (e.g., a dielectric material formed in multiple layers, as known in the art) and one or more conductive pathways (not shown) to route power, ground, and signals through the dielectric material (e.g., including conductive traces and/or conductive vias, as shown). In some embodiments, the insulating material of the substrate 102 may be a dielectric material, such as an organic dielectric material, a fire retardant grade 4 material (FR-4), BT resin, polyimide materials, glass reinforced epoxy matrix materials, organic dielectrics with inorganic fillers or low-k and ultra low-k dielectric (e.g., carbon-doped dielectrics, fluorine-doped dielectrics, porous dielectrics, and organic polymeric dielectrics). In particular, when the substrate 102 is formed using standard PCB processes, the substrate 102 may include FR-4, and the conductive pathways in the substrate 102 may be formed by patterned sheets of copper separated by build-up layers of the FR-4. The conductive pathways in the substrate 102 may be bordered by liner materials, such as adhesion liners and/or barrier liners, as suitable. In some embodiments, the substrate 102 may be a coreless substrate, a UTC substrate, a wafer level packaging, or any other suitable package designed to minimize z-height, as is known in the art. The substrate 102 may include conductive pathways (not shown) that allow power, ground, and other electrical signals to move between the die 114 and the substrate 102. In some embodiments, the die 114 may not be coupled to a substrate 102, but may instead be coupled to an other die, an interposer, such as a silicon interposer, a bridge interposer, or a glass substrate interposer, a package substrate, or a circuit board, such as a PCB.

In some embodiments, the substrate 102 may be formed using a lithographically defined via packaging process. In some embodiments, the substrate 102 may be manufactured using standard organic package manufacturing processes, and thus the substrate 102 may take the form of an organic package. In some embodiments, the substrate 102 may be a set of redistribution layers formed on a panel carrier by laminating or spinning on a dielectric material, and creating conductive vias and lines by laser drilling or ablation and plating. In some embodiments, the substrate 102 may be formed on a removable carrier using any suitable technique, such as a redistribution layer technique. Any method known in the art for fabrication of the substrate 102 may be used, and for the sake of brevity, such methods will not be discussed in further detail herein.

In some embodiments, the substrate 102 may be a lower density medium and the die 114 may be a higher density medium or have an area with a higher density medium. As used herein, the term “lower density” and “higher density” are relative terms indicating that the conductive pathways (e.g., including conductive interconnects, conductive lines, and conductive vias) in a lower density medium are larger and/or have a greater pitch than the conductive pathways in a higher density medium. In some embodiments, a higher density medium may be manufactured using a modified semi-additive process or a semi-additive build-up process with advanced lithography (with small vertical interconnect features formed by advanced laser or lithography processes), while a lower density medium may be a PCB manufactured using a standard PCB process (e.g., a standard subtractive process using etch chemistry to remove areas of unwanted copper, and with coarse vertical interconnect features formed by a standard laser process). In other embodiments, the higher density medium may be manufactured using semiconductor fabrication process, such as a single damascene process or a dual damascene process.

The microelectronic assembly 100 may further include a circuit board 133. The first conductive contacts 134 on the first surface 170-1 of the substrate 102 may be coupled to conductive contacts 132 on a surface of the circuit board 133 via second level interconnects 130. In some embodiments, the second level interconnects 130 may include solder balls (as illustrated in FIG. 1) for a ball grid array (BGA) coupling; in other embodiments, the second level interconnects 130 may include solder paste contacts to provide land grid array (LGA) interconnects, or any other suitable interconnect. In some embodiments, the circuit board 133 may include one or more components disposed thereon (not shown). The circuit board 133 may include conductive pathways (not shown) that allow power, ground, and other electrical signals to move between the circuit board 133 and the substrate 102 as well as between the circuit board 133 and the die 114, as known in the art.

Although a single die 114 is illustrated in FIG. 1, this is simply an example, and the microelectronic assembly 100 may include one or more dies 114. The dies may perform any suitable functionality, and may include processing devices, memory, communications devices, sensors, or any other computing components or circuitry. For example, the dies may include a central processing unit (CPU), a platform controller hub (PCH), a dynamic random access memory (DRAM), a graphic processing unit (GPU), and a field programmable gate array (FPGA).

Although FIG. 1 illustrates a single IC package (e.g., substrate 102 with die 114) disposed on the circuit board 133, this is simply for ease of illustration and multiple IC packages with multiple dies may be disposed on the circuit board 133. In some embodiments, the circuit board 133 may be a PCB (e.g., a motherboard). In some embodiments, the circuit board 133 may be another IC package, and the microelectronic assembly 100 may be a package-on-package structure. In some embodiments, the circuit board 133 may be an interposer, and the microelectronic assembly 100 may be a package-on-interposer structure.

Many of the elements of the microelectronic assembly 100 of FIG. 1 are included in other ones of the accompanying figures; the discussion of these elements is not repeated when discussing these figures, and any of these elements may take any of the forms disclosed herein. Some of the elements of the microelectronic assembly 100 of FIG. 1 are not included in other ones of the accompanying figures for simplicity, but a microelectronic assembly 100 may include these omitted elements. In some embodiments, individual ones of the microelectronic assemblies 100 disclosed herein may serve as a system-in-package (SiP) in which multiple dies 114 having different functionality are included. In such embodiments, the microelectronic assembly 100 may be referred to as a SiP.

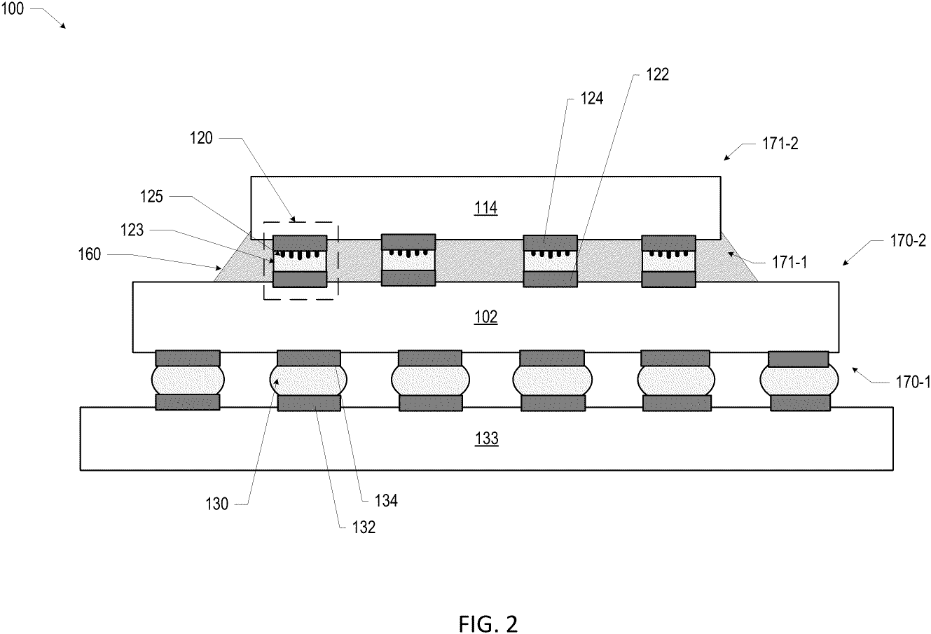

FIG. 2 is a side, cross-sectional view of a microelectronic assembly 100, in accordance with various embodiments. The microelectronic assembly 100 may include a die 114 electrically coupled to a substrate 102 by interconnects 120. The interconnects 120 may include nanowires 125 and an IMC 123 that conductively couple the conductive contacts 124 on the die 114 and second conductive contacts 122 on the substrate 102. As shown in FIG. 2, the solder material (e.g., the solder material 121 in FIG. 1) may be completely converted to an IMC 123. Smaller interconnect pitches may be further enabled by the complete conversion of the solder material to the IMC forming a high temperature stable interconnect.

FIG. 3 is a side, cross-sectional view of a microelectronic assembly 100, in accordance with various embodiments. The microelectronic assembly 100 may include a die 114 electrically coupled to a substrate 102 by interconnects 120. The interconnects 120 may include nanowires 125 and an IMC 123 that conductively couple the conductive contacts 124 on the die 114 and second conductive contacts 122 on the substrate 102. The nanowires 125 may have any suitable size. For example, a nanowire 125, when formed, may have a height (e.g., z-dimension) between 1 micron and 2 microns. In some embodiments, a z-height of a nanowire 125 may be less than or equal to a z-height of solder on second conductive contacts 122 on the substrate 102, prior to forming the interconnect 120. In some embodiments, a height 191 of a nanowire 125 may be reduced during the reflow process, such that a height 191 of the nanowire 125 in an interconnect 120 (e.g., a portion of the nanowire that remains intact) may be less than when formed. In some embodiments, a height the nanowires 125 (e.g., a portion of the nanowire that remains intact) may increase a surface roughness of the conductive contacts 124. For example, after solder reflow, a surface roughness of a conductive contact 124 may be greater than a surface roughness of a second conductive contact 122.

Any suitable techniques may be used to manufacture the microelectronic assemblies 100 disclosed herein. For example, FIGS. 4A-4C are side, cross-sectional views of an exemplary process for manufacturing a microelectronic assembly, in accordance with various embodiments. Although the operations discussed below with reference to FIGS. 4A-4C (and others of the accompanying drawings representing manufacturing processes) are illustrated in a particular order, these operations may be performed in any suitable order. Further, additional operations which are not illustrated may also be performed without departing from the scope of the present disclosure. Also, various ones of the operations discussed herein with respect to FIGS. 4A-4C may be modified in accordance with the present disclosure to fabricate others of microelectronic assembly 100 disclosed herein.

FIG. 4A illustrates an assembly subsequent to forming nanowires 125 on conducive contacts 122 on a second surface 170-2 of a substrate 102, depositing a solder material 121 on conductive contacts 124 on a first surface 171-1 of a die 114, and melting the solder material 121. The nanowires 125 may be formed using any suitable process, such as electroplating, and may be formed to have any suitable height, which may depend on the plating time and/or plating current. The nanowires 125 may be formed of any suitable conductive material, such as a metal or metal alloy. The nanowires 125 may be formed to have any suitable profile shape, such as domed (e.g., having longer height in the middle and shorter height on the edges, as shown in FIG. 4A) or linear (e.g., having a same height). The solder material 121 may include any suitable material, as described above with reference to FIG. 1. In some embodiments, the melting of the solder material 121 may be part of a solder reflow process. In some embodiments, a barrier layer (not shown), such as a nickel diffusion barrier layer, may be deposited on the conductive contacts 124 prior to depositing the solder material 121 (e.g., the barrier layer may be between the conductive contacts 124 and the solder material 121).

FIG. 4B illustrates an assembly subsequent to bringing the melted solder material 121 of the die 114 in contact with the nanowires 125 of the substrate 102 causing the nanowires 125 to pull the solder material 121 towards the conductive contacts 122 of the substrate 102, for example, by capillary action. Any suitable method may be used to place the die 114, for example, automated pick-and-place. The IMC 123 may be formed at a surface of the conductive contacts 124, at a surface of the conductive contact 122, and at surfaces of the nanowires 125, then may surround the nanowires 125 and extend between the conductive contacts 122 and 124. When the IMC 123 forms, the nanowires 125 may be reduced in height (e.g., z-direction) and/or diameter (e.g., y-direction and/or x-direction).

FIG. 4C illustrates an assembly subsequent to completing the solder reflow process during which first level interconnects 120 are formed by the solder material converting to an IMC 123 that mechanically and electrically couples the die 114 to the top surface 170-2 of the substrate 102, and depositing an underfill material 160 around the interconnects 120. In some embodiments, the solder material may completely convert to an IMC. In other embodiments, only a portion of the solder material may convert to an IMC. The underfill material 160 may be formed of any suitable material, as described above with reference to FIG. 1, and may be dispensed using any suitable technique. Further manufacturing operations may be performed on the microelectronic assembly 100 of FIG. 4C to form other microelectronic assembly 100; for example, the conductive contacts 134 with solder (not shown) on a first surface 170-1 of the substrate 102 may be used to couple the microelectronic assembly 100 of FIG. 4C to a circuit board 133 via second level interconnects 130, similar to the microelectronic assembly 100 of FIG. 2. The assembly of FIG. 4C may itself be a microelectronic assembly 100, as shown. If multiple assemblies are manufactured together, the assemblies may be singulated after curing.

FIGS. 5A-5D are side, cross-sectional views of an exemplary process for manufacturing a microelectronic assembly, in accordance with various embodiments. FIG. 5A illustrates an assembly subsequent to forming nanowires 125 on conducive contacts 124 on a first surface 171-1 of a die 114, depositing a solder material 121 on conductive contacts 122 on a second surface 170-2 of a substrate 102, and reflowing the solder material 121. The conductive contacts 124 may have any suitable height 195 (e.g., z-height). As shown in FIG. 5A, a first conductive contact 124-1 may have a first height 195-1 and a second conductive contact 124-2 having a second height 195-2 different than the first height 195-1 (e.g., the first height 195-1 may be greater than a second height 195-2). The nanowires 125 may be formed using any suitable process, such as electroplating, and may be formed of any suitable conductive material, such as a metal or metal alloy. The nanowires 125 may be formed to have any suitable profile shape, such as domed (e.g., having longer height in the middle and shorter height on the edges, as shown in FIG. 5A) or linear (e.g., having a same height). The solder material 121 may include any suitable material, as described above with reference to FIG. 1. In some embodiments, the melting of the solder material 121 may be part of a solder reflow process.

FIG. 5B illustrates an assembly subsequent to bringing some of the nanowires 125 of the die 114 in contact with the melted solder material 121 of the substrate 102 causing the nanowires 125 to pull the solder material 121 towards the conductive contacts 124-1 of the die 114, for example, by capillary action. Any suitable method may be used to place the die 114, for example, automated pick-and-place.

FIG. 5C illustrates an assembly subsequent to bringing the remaining nanowires 125 of the die 114 in contact with the melted solder material 121 of the substrate 102 causing the nanowires 125 to pull the solder material 121 towards the conductive contacts 124-2 of the die 114, for example, by capillary action. The nanowires 125 and solder material 121 may enable improved coplanarity by compensating for conductive contacts 124-1, 124-2 having different heights 195-1, 195-2, solder material having different heights (not shown), warpage of the die 114 (not shown), and/or warpage of the substrate 102 (not shown) causing height differences.

FIG. 5D illustrates an assembly subsequent to completing the solder reflow process during which first level interconnects 120 are formed by the solder material converting to an IMC 123 that mechanically and electrically couples the die 114 to the top surface 170-2 of the substrate 102, and depositing an underfill material 160 around the interconnects 120. The IMC 123 may be formed as described above with reference to FIG. 4. In some embodiments, the solder material may completely convert to an IMC 123. In other embodiments, only a portion of the solder material may convert to an IMC 123. In embodiments where the solder material completely converts to an IMC 123, a height 197-1 of the IMC 123 of the first conductive contact 124-1 may be different than a height 197-2 of the IMC 123 of the second conductive contact 124-2 (e.g., the first height 197-1 may be smaller than the second height 197-2). In embodiments where only a portion of the solder material converts to an IMC 123, a height 195 of an IMC 123 may vary depending on a height 195, as shown in FIG. 5A, of a conductive contact 124 (e.g., a second conductive contact 124-2 having a second (i.e., smaller) height 195-2 may have a greater IMC height 197). The underfill material 160 may be formed of any suitable material, as described above with reference to FIG. 1, and may be dispensed using any suitable technique. Further manufacturing operations may be performed on the microelectronic assembly 100 of FIG. 5D to form other microelectronic assembly 100; for example, the conductive contacts 134 with solder (not shown) on a first surface 170-1 of the substrate 102 may be used to couple the microelectronic assembly 100 of FIG. 5D to a circuit board 133 via second level interconnects 130, similar to the microelectronic assembly 100 of FIG. 2. The assembly of FIG. 5D may itself be a microelectronic assembly 100, as shown. If multiple assemblies are manufactured together, the assemblies may be singulated after curing.

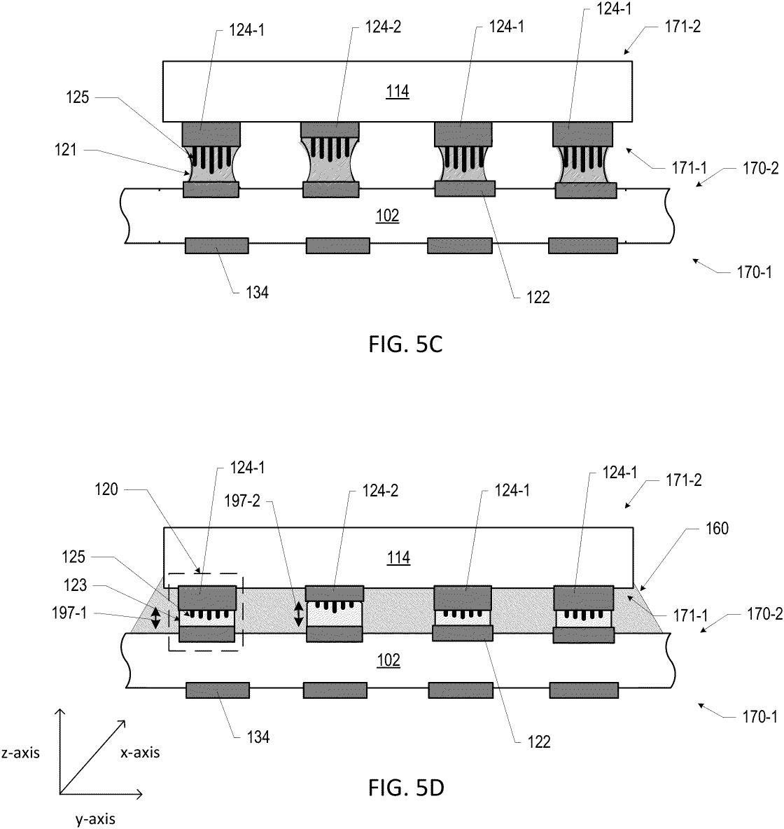

FIG. 6 is a flow diagram of an example method of manufacturing a microelectronic assembly, in accordance with various embodiments. At 602, nanowires 125 may be formed on first conductive contacts of a first component (e.g., on first conductive contacts 124 of a die 114, as shown in FIG. 3). At 604, solder material 121 may be deposited on second conductive contacts of a second component (e.g., second conductive contacts 122 of a substrate 102) and the solder material 121 may be melted or reflowed. In some embodiments, the first conductive component is a substrate and the second component is a die, as described above with reference to FIG. 4. At 606, the nanowires 125 on the first conductive contacts of the first component may be brought into contact with the melted solder material 121 on respective second conductive contacts on the second component. At 608, the first component may be electrically coupled to the second component by first level interconnects 120 and by converting at least a portion of the solder material 121 to an IMC 123. Optionally, an underfill material 160 may be dispensed around the first level interconnects 120 and the assembly, including the underfill material 160, may be cured to further secure the die 114 to the substrate 102.

The microelectronic assemblies disclosed herein may be included in any suitable electronic device. FIGS. 7-9 illustrate various examples of apparatuses that may be included in, or that may include, one or more of any of the microelectronic assemblies disclosed herein.

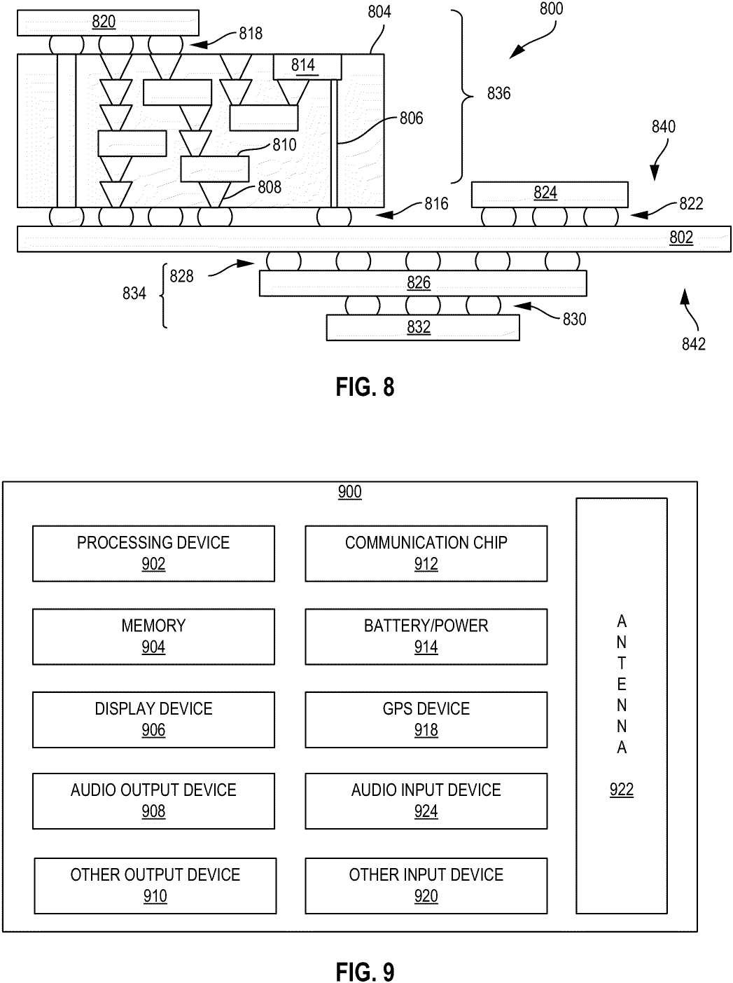

FIGS. 7A and 7B are top views of a wafer 701 and dies 705 that may be included in any of the microelectronic assemblies disclosed herein. The wafer 701 may be composed of semiconductor material and may include one or more dies 705 having IC elements formed on a surface of the wafer 701. Each of the dies 705 may be a repeating unit of a semiconductor product that includes any suitable IC. After the fabrication of the semiconductor product is complete, the wafer 701 may undergo a singulation process in which each of the dies 705 is separated from one another to provide discrete “chips” of the semiconductor product. The die 705 may include one or more transistors (e.g., some of the transistors 740 of FIG. 7C, discussed below) and/or supporting circuitry to route electrical signals to the transistors, as well as any other IC components. In some embodiments, the wafer 701 or the die 705 may include a memory device (e.g., a static random access memory (SRAM) device), a logic device (e.g., AND, OR, NAND, or NOR gate), or any other suitable circuit element. Multiple ones of these devices may be combined on a single die 705. For example, a memory array formed by multiple memory devices may be formed on a same die 705 as a processing device (e.g., the processing device 902 of FIG. 9) or other logic that is configured to store information in the memory devices or execute instructions stored in the memory array. In some embodiments, the die 705 may include circuitry that is to couple to and interact with circuitry provided by integral devices in the package substrate, after the die 705 is coupled to the package substrate, as discussed above.

FIG. 7C is a cross-sectional side view of an IC device 700 that may be included in a die that may be included in any of the microelectronic assemblies disclosed herein. In particular, one or more of the IC devices 700 may be included in one or more dies. The IC device 700 may be formed on a substrate 702 (e.g., the wafer 701 of FIG. 7A) and may be included in a die (e.g., the die 705 of FIG. 7B). The substrate 702 may be a semiconductor substrate composed of semiconductor material systems including, for example, N-type or P-type materials systems. The substrate 702 may include, for example, a crystalline substrate formed using a bulk silicon or a silicon-on-insulator substructure. In some embodiments, the substrate 702 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 702. Although a few examples of materials from which the substrate 702 may be formed are described here, any material that may serve as a foundation for an IC device 700 may be used. The substrate 702 may be part of a singulated die (e.g., the dies 705 of FIG. 7B) or a wafer (e.g., the wafer 701 of FIG. 7A).

The IC device 700 may include one or more device layers 704 disposed on the substrate 702. The device layer 704 may include features of one or more transistors 740 (e.g., metal oxide semiconductor field-effect transistors (MOSFETs)) formed on the substrate 702. The device layer 704 may include, for example, one or more source and/or drain (S/D) regions 720, a gate 722 to control current flow in the transistors 740 between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7C and may include a wide variety of other types and configurations such as, for example, planar transistors, nonplanar transistors, or a combination of both. Nonplanar transistors may include FinFET transistors, such as double-gate transistors or tri-gate transistors, and wraparound or all-around gate transistors, such as nanoribbon and nanowire transistors.

Each transistor 740 may include a gate 722 formed of at least two layers, a gate dielectric layer and a gate electrode layer. The gate dielectric layer may include one layer or a stack of layers. The one or more layers may include silicon oxide, silicon dioxide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer may be formed on the gate dielectric layer and may include at least one P-type work-function metal or N-type work-function metal, depending on whether the transistor 740 is to be a PMOS or an NMOS transistor. In some implementations, the gate electrode layer may consist of a stack of two or more metal layers, where one or more metal layers are work-function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, and conductive metal oxides (e.g., ruthenium oxide). For an NMOS transistor, metals that may be used for the gate electrode include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, when viewed as a cross section of the transistor 740 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the substrate 702 adjacent to the gate 722 of each transistor 740. The S/D regions 720 may be formed using either an implantation/diffusion process or an etching/deposition process, for example. In the former process, dopants such as boron, aluminum, antimony, phosphorous, or arsenic may be ion-implanted into the substrate 702 to form the S/D regions 720. An annealing process that activates the dopants and causes them to diffuse farther into the substrate 702 may follow the ion-implantation process. In the latter process, the substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the transistors 740 of the device layer 704 through one or more interconnect layers disposed on the device layer 704 (illustrated in FIG. 7C as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form an interlayer dielectric (ILD) stack 719 of the IC device 700.

The interconnect structures 728 may be arranged within the interconnect layers 706-710 to route electrical signals according to a wide variety of designs (in particular, the arrangement is not limited to the particular configuration of interconnect structures 728 depicted in FIG. 7C). Although a particular number of interconnect layers 706-710 is depicted in FIG. 7C, embodiments of the present disclosure include IC devices having more or fewer interconnect layers than depicted.

In some embodiments, the interconnect structures 728 may include trench structures 728a (sometimes referred to as “lines”) and/or via structures 728b (sometimes referred to as “holes”) filled with an electrically conductive material such as a metal. The trench structures 728a may be arranged to route electrical signals in a direction of a plane that is substantially parallel with a surface of the substrate 702 upon which the device layer 704 is formed. For example, the trench structures 728a may route electrical signals in a direction in and out of the page from the perspective of FIG. 7C. The via structures 728b may be arranged to route electrical signals in a direction of a plane that is substantially perpendicular to the surface of the substrate 702 upon which the device layer 704 is formed. In some embodiments, the via structures 728b may electrically couple trench structures 728a of different interconnect layers 706-710 together.

The interconnect layers 706-710 may include a dielectric material 726 disposed between the interconnect structures 728, as shown in FIG. 7C. In some embodiments, the dielectric material 726 disposed between the interconnect structures 728 in different ones of the interconnect layers 706-710 may have different compositions; in other embodiments, the composition of the dielectric material 726 between different interconnect layers 706-710 may be the same.

A first interconnect layer 706 (referred to as Metal 1 or “M1”) may be formed directly on the device layer 704. In some embodiments, the first interconnect layer 706 may include trench structures 728a and/or via structures 728b, as shown. The trench structures 728a of the first interconnect layer 706 may be coupled with contacts (e.g., the S/D contacts 724) of the device layer 704.

A second interconnect layer 708 (referred to as Metal 2 or “M2”) may be formed directly on the first interconnect layer 706. In some embodiments, the second interconnect layer 708 may include via structures 728b to couple the trench structures 728a of the second interconnect layer 708 with the trench structures 728a of the first interconnect layer 706. Although the trench structures 728a and the via structures 728b are structurally delineated with a line within each interconnect layer (e.g., within the second interconnect layer 708) for the sake of clarity, the trench structures 728a and the via structures 728b may be structurally and/or materially contiguous (e.g., simultaneously filled during a dual-damascene process) in some embodiments.

A third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706.

The IC device 700 may include a solder resist material 734 (e.g., polyimide or similar material) and one or more bond pads 736 formed on the interconnect layers 706-710. The bond pads 736 may provide the contacts to couple to first level interconnects, for example. The bond pads 736 may be electrically coupled with the interconnect structures 728 and configured to route the electrical signals of the transistor(s) 740 to other external devices. For example, solder bonds may be formed on the one or more bond pads 736 to mechanically and/or electrically couple a chip including the IC device 700 with another component (e.g., a circuit board). The IC device 700 may have other alternative configurations to route the electrical signals from the interconnect layers 706-710 than depicted in other embodiments. For example, the bond pads 736 may be replaced by or may further include other analogous features (e.g., posts) that route the electrical signals to external components.

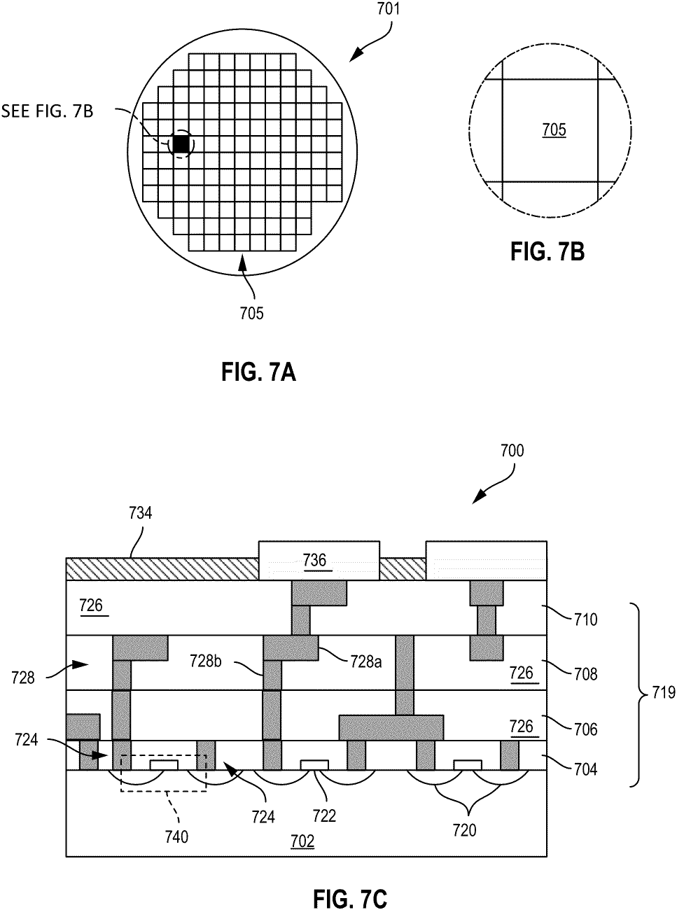

FIG. 8 is a cross-sectional side view of an IC device assembly 800 that may include any of the embodiments of the microelectronic assemblies disclosed herein. The IC device assembly 800 includes a number of components disposed on a circuit board 802. The IC device assembly 800 may include components disposed on a first face 840 of the circuit board 802 and an opposing second face 842 of the circuit board 802; generally, components may be disposed on one or both faces 840 and 842.

In some embodiments, the circuit board 802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 802. In other embodiments, the circuit board 802 may be a non-PCB substrate.

The IC device assembly 800 illustrated in FIG. 8 includes a package-on-interposer structure 836 coupled to the first face 840 of the circuit board 802 by coupling components 816. The coupling components 816 may electrically and mechanically couple the package-on-interposer structure 836 to the circuit board 802, and may include solder balls (as shown in FIG. 8), male and female portions of a socket, an adhesive, an underfill material, and/or any other suitable electrical and/or mechanical coupling structure.

The package-on-interposer structure 836 may include an IC package 820 coupled to an interposer 804 by coupling components 818. The coupling components 818 may take any suitable form for the application, such as the forms discussed above with reference to the coupling components 816. For example, the coupling components 818 may be second level interconnects. Although a single IC package 820 is shown in FIG. 8, multiple IC packages may be coupled to the interposer 804; indeed, additional interposers may be coupled to the interposer 804. The interposer 804 may provide an intervening substrate used to bridge the circuit board 802 and the IC package 820. The IC package 820 may be or include, for example, a die (the die 705 of FIG. 7B), an IC device (e.g., the IC device 700 of FIG. 7C), or any other suitable component. In particular, the IC package 820 may take any of the embodiments of the IC package substrates disclosed herein, and may include a package substrate with a conductive element having a cavity for a passive component and where the conductive element is electrically connected to the passive component. Generally, the interposer 804 may spread a connection to a wider pitch or reroute a connection to a different connection. For example, the interposer 804 may couple the IC package 820 (e.g., a die) to a ball grid array (BGA) of the coupling components 816 for coupling to the circuit board 802. In the embodiment illustrated in FIG. 8, the IC package 820 and the circuit board 802 are attached to opposing sides of the interposer 804; in other embodiments, the IC package 820 and the circuit board 802 may be attached to a same side of the interposer 804. In some embodiments, three or more components may be interconnected by way of the interposer 804.

The interposer 804 may be formed of an epoxy resin, a fiberglass-reinforced epoxy resin, a ceramic material, or a polymer material such as polyimide. In some embodiments, the interposer 804 may be formed of alternate rigid or flexible materials that may include the same materials used in a semiconductor substrate, such as silicon, germanium, and other group III-V and group IV materials. The interposer 804 may include metal interconnects 808 and vias 810, including but not limited to through-silicon vias (TSVs) 806. The interposer 804 may further include embedded devices 814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 804. The package-on-interposer structure 836 may take the form of any of the package-on-interposer structures known in the art.

The IC device assembly 800 may include an IC package 824 coupled to the first face 840 of the circuit board 802 by coupling components 822. The coupling components 822 may take the form of any of the embodiments discussed above with reference to the coupling components 816, and the IC package 824 may take the form of any of the embodiments discussed above with reference to the IC package 820. In particular, the IC package 824 may take the form of any of the embodiments of the IC package disclosed herein, and may include a package substrate with a conductive element having a cavity for a passive component and where the conductive element is electrically connected to the passive component.

The IC device assembly 800 illustrated in FIG. 8 includes a package-on-package structure 834 coupled to the second face 842 of the circuit board 802 by coupling components 828. The package-on-package structure 834 may include an IC package 826 and an IC package 832 coupled together by coupling components 830 such that the IC package 826 is disposed between the circuit board 802 and the IC package 832. The coupling components 828 and 830 may take the form of any of the embodiments of the coupling components 816 discussed above, and the IC packages 826 and 832 may take the form of any of the embodiments of the IC package 820 discussed above. In particular, the IC packages 826 and 832 may take any of the embodiments of the IC package substrate with a conductive element having a cavity for a passive component and where the conductive element is electrically connected to the passive component disclosed herein.

FIG. 9 is a block diagram of an example computing device 900 that may include one or more of the microelectronic assemblies disclosed herein. A number of components are illustrated in FIG. 9 as included in the computing device 900, but any one or more of these components may be omitted or duplicated, as suitable for the application. In some embodiments, some or all of the components included in the computing device 900 may be attached to one or more motherboards. In some embodiments, some or all of these components are fabricated onto a single system-on-a-chip (SoC) die.

Additionally, in various embodiments, the computing device 900 may include interface circuitry for coupling to the one or more components. For example, the computing device 900 may not include a display device 906, but may include display device interface circuitry (e.g., a connector and driver circuitry) to which a display device 906 may be coupled. In another set of examples, the computing device 900 may not include an audio input device 924 or an audio output device 908, but may include audio input or output device interface circuitry (e.g., connectors and supporting circuitry) to which an audio input device 924 or audio output device 908 may be coupled.

The computing device 900 may include a processing device 902 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 900 may include a memory 904, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 904 may include memory that shares a die with the processing device 902. This memory may be used as cache memory and may include embedded dynamic random access memory (eDRAM) or spin transfer torque magnetic random-access memory (STT-MRAM).

In some embodiments, the computing device 900 may include a communication chip 912 (e.g., one or more communication chips). For example, the communication chip 912 may be configured for managing wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 912 may operate in accordance with other wireless protocols in other embodiments. The computing device 900 may include an antenna 922 to facilitate wireless communications and/or to receive other wireless communications (such as AM or FM radio transmissions).

In some embodiments, the communication chip 912 may manage wired communications, such as electrical, optical, or any other suitable communication protocols (e.g., the Ethernet). As noted above, the communication chip 912 may include multiple communication chips. For instance, a first communication chip 912 may be dedicated to shorter-range wireless communications such as Wi-Fi or Bluetooth, and a second communication chip 912 may be dedicated to longer-range wireless communications such as GPS, EDGE, GPRS, CDMA, WiMAX, LTE, EV-DO, or others. In some embodiments, a first communication chip 912 may be dedicated to wireless communications, and a second communication chip 912 may be dedicated to wired communications.

The computing device 900 may include battery/power circuitry 914. The battery/power circuitry 914 may include one or more energy storage devices (e.g., batteries or capacitors) and/or circuitry for coupling components of the computing device 900 to an energy source separate from the computing device 900 (e.g., AC line power).

The computing device 900 may include a display device 906 (or corresponding interface circuitry, as discussed above). The display device 906 may include any visual indicators, such as a heads-up display, a computer monitor, a projector, a touchscreen display, a liquid crystal display (LCD), a light-emitting diode display, or a flat panel display, for example.

The computing device 900 may include an audio output device 908 (or corresponding interface circuitry, as discussed above). The audio output device 908 may include any device that generates an audible indicator, such as speakers, headsets, or earbuds, for example.

The computing device 900 may include an audio input device 924 (or corresponding interface circuitry, as discussed above). The audio input device 924 may include any device that generates a signal representative of a sound, such as microphones, microphone arrays, or digital instruments (e.g., instruments having a musical instrument digital interface (MIDI) output).

The computing device 900 may include a global positioning system (GPS) device 918 (or corresponding interface circuitry, as discussed above). The GPS device 918 may be in communication with a satellite-based system and may receive a location of the computing device 900, as known in the art.

The computing device 900 may include an other output device 910 (or corresponding interface circuitry, as discussed above). Examples of the other output device 910 may include an audio codec, a video codec, a printer, a wired or wireless transmitter for providing information to other devices, or an additional storage device.

The computing device 900 may include an other input device 920 (or corresponding interface circuitry, as discussed above). Examples of the other input device 920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 900 may have any desired form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 900 may be any other electronic device that processes data.

The following examples pertain to further embodiments. The various features of the different embodiments may be variously combined with some features included and others excluded to suit a variety of different applications.

Example 1 is a microelectronic assembly, including a die having a first conductive contact on a surface; a substrate having a second conductive contact on a surface; and an interconnect electrically coupling the first conductive contact of the die and the second conductive contact of the substrate, wherein the interconnect includes a portion of a nanowire on the second conductive contact and an intermetallic compound (IMC) surrounding at least a portion of the nanowire on the second conductive contact.

Example 2 may include the subject matter of Example 1, and may further specify that a material of the nanowire includes copper, nickel, gold, silver, or palladium, or an alloy thereof.

Example 3 may include the subject matter of Examples 1 or 2, and may further specify that the IMC extends from the first conductive contact to the second conductive contact.

Example 4 may include the subject matter of any of Examples 1-3, further including an underfill material around the interconnect.

Example 5 may include the subject matter of any of Examples 1-4, and may further specify that the interconnect further includes a solder material between the IMC and the second conductive contact.

Example 6 may include the subject matter of Example 5, and may further specify that the solder material includes tin; tin and silver; tin and bismuth; tin, silver, and bismuth; indium; indium and tin; antimony; or gallium.

Example 7 may include the subject matter of Example 5, and may further specify that the IMC is a first IMC, and wherein the interconnect further includes a second IMC between the solder material and the second conductive contact.

Example 8 may include the subject matter of any of Examples 1-7, and may further specify that the interconnect is one of a plurality of interconnects and a pitch of the plurality of interconnects is between 3 microns and 20 microns.

Example 9 may include the subject matter of any of Examples 1-8, and may further specify that the substrate includes a first surface with a third conductive contact and an opposing second surface with the second conductive contact, and the microelectronic assembly further includes a circuit board electrically coupled to the third conductive contact on the first surface of the substrate.

Example 10 is a microelectronic assembly, including a microelectronic component having a first conductive contact with nanowires extending from a surface of the first conductive contact; a substrate having a second conductive contact; and an interconnect electrically coupling the first conductive contact of the microelectronic component and the second conductive contact of the substrate, wherein the interconnect includes an intermetallic compound (IMC) surrounding at least a portion of the nanowires on the first conductive contact.

Example 11 may include the subject matter of Example 10, and may further specify that a material of the nanowires includes copper, nickel, gold, silver, or palladium, or an alloy thereof.

Example 12 may include the subject matter of Examples 10 or 11, and may further specify that the IMC extends from the first conductive contact to the second conductive contact.

Example 13 may include the subject matter of any of Examples 10-12, and may further specify that the interconnect further includes a solder material between the IMC and the second conductive contact, and wherein the solder material includes tin; tin and silver; tin and bismuth; tin, silver, and bismuth; indium; indium and tin; antimony; or gallium.

Example 14 may include the subject matter of any of Examples 10-13, and may further specify that the interconnect is one of a plurality of interconnects and a pitch of the plurality of interconnects is between 3 microns and 20 microns.

Example 15 may include the subject matter of any of Examples 10-14, and may further specify that the microelectronic component is a die selected from the group consisting of a central processing unit, a platform controller hub, a memory die, a field programmable gate array silicon die, and graphic processing unit.

Example 16 is a method for fabricating a microelectronic assembly, the method including electroplating nanowires on a first conductive contact on a first component; depositing a solder material on a second conductive contact on a second component; melting the solder material on the second conductive contact; placing the nanowires of the first conductive contact in contact with the solder material of the second conductive contact; and forming an interconnect between the first component and the second component that includes an intermetallic compound surrounding the nanowires on the first conductive contact.

Example 17 may include the subject matter of Example 16, and may further specify that the first component is a substrate and the second component is a die.

Example 18 may include the subject matter of Example 16, and may further specify that the first component is a die and the second component is a substrate.

Example 19 may include the subject matter of any of Examples 16-18, and may further specify that a material of the nanowires includes copper, nickel, gold, silver, or palladium, or an alloy thereof.

Example 20 may include the subject matter of any of Examples 16-19, and may further specify that the solder material includes tin; tin and silver; tin and bismuth; tin, silver, and bismuth; indium; indium and tin; antimony; or gallium.

Example 21 may include the subject matter of any of Examples 16-20, and may further specify that the interconnect is one of a plurality of interconnects and a pitch of the plurality of interconnects is between 3 microns and 20 microns.

Example 22 is a computing device, including a circuit board; and an integrated circuit (IC) package electrically coupled to the circuit board, wherein the IC package includes a die having a first conductive contact; a package substrate having a second conductive contact; and an interconnect electrically coupling the first conductive contact of the die and the second conductive contact of the package substrate, wherein the interconnect includes nanowires on the first conductive contact and an intermetallic compound (IMC) surrounding the nanowires on the first conductive contact.

Example 23 may include the subject matter of Example 22, and may further specify that the die is one of a central processing unit, a platform controller hub, a memory die, a field programmable gate array silicon die, and graphic processing unit.

Example 24 may include the subject matter of Examples 22 or 23, and may further specify that the computing device is included in a server device.

Example 25 may include the subject matter of Examples 22 or 23, and may further specify that the computing device is included in a portable computing device.

Example 26 may include the subject matter of Examples 22 or 23, and may further specify that the computing device is included in a wearable computing device.

1. A microelectronic assembly, comprising:
a die having a first conductive contact on a surface;
a substrate having a second conductive contact on a surface; and
an interconnect electrically coupling the first conductive contact of the die and the second conductive contact of the substrate, wherein the interconnect includes a portion of a nanowire on the second conductive contact and an intermetallic compound (IMC) surrounding at least a portion of the nanowire on the second conductive contact.

2. The microelectronic assembly of claim 1, wherein a material of the nanowire includes copper, nickel, gold, silver, or palladium, or an alloy thereof.

3. The microelectronic assembly of claim 1, wherein the IMC extends from the first conductive contact to the second conductive contact.

4. The microelectronic assembly of claim 1, further including an underfill material around the interconnect.

5. The microelectronic assembly of claim 1, wherein the interconnect further includes a solder material between the IMC and the second conductive contact.

6. The microelectronic assembly of claim 5, wherein the solder material includes tin; tin and silver; tin and bismuth; tin, silver, and bismuth; indium; indium and tin; antimony; or gallium.

7. The microelectronic assembly of claim 5, wherein the IMC is a first IMC, and wherein the interconnect further includes a second IMC between the solder material and the second conductive contact.

8. The microelectronic assembly of claim 1, wherein the interconnect is one of a plurality of interconnects and a pitch of the plurality of interconnects is between 3 microns and 20 microns.

9. The microelectronic assembly of claim 1, wherein the substrate includes a first surface with a third conductive contact and an opposing second surface with the second conductive contact, and the microelectronic assembly further includes:
a circuit board electrically coupled to the third conductive contact on the first surface of the substrate.

10. A microelectronic assembly, comprising:
a microelectronic component having a first conductive contact with nanowires extending from a surface of the first conductive contact;
a substrate having a second conductive contact; and
an interconnect electrically coupling the first conductive contact of the microelectronic component and the second conductive contact of the substrate, wherein the interconnect includes an intermetallic compound (IMC) surrounding at least a portion of the nanowires on the first conductive contact.

11. The microelectronic assembly of claim 10, wherein a material of the nanowires includes copper, nickel, gold, silver, or palladium, or an alloy thereof.

12. The microelectronic assembly of claim 10, wherein the IMC extends from the first conductive contact to the second conductive contact.

13. The microelectronic assembly of claim 10, wherein the interconnect further includes a solder material between the IMC and the second conductive contact, and wherein the solder material includes tin; tin and silver; tin and bismuth; tin, silver, and bismuth; indium; indium and tin; antimony; or gallium.

14. The microelectronic assembly of claim 10, wherein the interconnect is one of a plurality of interconnects and a pitch of the plurality of interconnects is between 3 microns and 20 microns.

15. The microelectronic assembly of claim 10, wherein the microelectronic component is a die selected from the group consisting of a central processing unit, a platform controller hub, a memory die, a field programmable gate array silicon die, and graphic processing unit.

16. A method for fabricating a microelectronic assembly, the method comprising:
electroplating nanowires on a first conductive contact on a first component;
depositing a solder material on a second conductive contact on a second component;
melting the solder material on the second conductive contact;
placing the nanowires of the first conductive contact in contact with the solder material of the second conductive contact; and
forming an interconnect between the first component and the second component that includes an intermetallic compound surrounding the nanowires on the first conductive contact.

17. The method of claim 16, wherein the first component is a substrate and the second component is a die.

18. The method of claim 16, wherein the first component is a die and the second component is a substrate.

19. The method of claim 16, wherein a material of the nanowires includes copper, nickel, gold, silver, or palladium, or an alloy thereof.

20. The method of claim 16, wherein the solder material includes tin; tin and silver; tin and bismuth; tin, silver, and bismuth; indium; indium and tin; antimony; or gallium.
